(19) United States
(12) Patent Application Publication
(10) Pub. No.: US 2025/0359245 A1
(43) Pub. Date: Nov. 20, 2025

(54) SEMICONDUCTOR LAYOUT WITH DUMMY PATTERNS AND METHOD OF MANUFACTURING THE SAME

(71) Applicant: UNITED MICROELECTRONICS CORP., Hsin-Chu City (TW)

(72) Inventors: Hsin-Hsien Chen, New Taipei City (TW); Kuo-Hsing Lee, Hsinchu County (TW); Chih-Kai Kang, Tainan City (TW)

(73) Assignee: UNITED MICROELECTRONICS CORP., Hsin-Chu City (TW)

(21) Appl. No.: 18/764,072

(22) Filed: Jul. 3, 2024

(30) Foreign Application Priority Data
May 17, 2024 (TW) 113118294

(51) Int. Cl. H01L 29/66; H01L 23/48; H01L 29/78; H10B 10/00

(52) U.S. Cl. CPC H10D 64/017; H01L 23/481; H10B 10/12; H10D 30/024; H10D 30/62

(57) ABSTRACT

A semiconductor layout with dummy patterns is provide in the present invention, including a substrate with a cell region and a dummy region adjacent to each other, multiple fins on the substrate, multiple gates on the substrate over the fins, multiple slot contacts on the substrate between the gates and connected with the fins, multiple polysilicon contacts on the gates in the cell region and connected therewith, and multiple dummy polysilicon contacts on the gates in the dummy region closest to the cell region and not connected with any interconnects, wherein the dummy polysilicon contacts are in reflection symmetrical to the polysilicon contacts closest to a boundary between the dummy region and the cell region with respect to the boundary.

### BACKGROUND OF THE INVENTION

### 1. Field of the Invention

The present invention relates generally to a semiconductor layout, and more specifically, to a semiconductor layout with dummy patterns.

### 2. Description of the Prior Art

In order to increase function density, semiconductor devices are often integrated with logic circuits and embedded static random-access memory (SRAM) units. Such applications are widespread in industrial and scientific research subsystems, automotive electronics, cell phones, digital cameras, microprocessors, etc. SRAM has advantages of storing data without refresh requirement. Its memory cell contains different numbers of transistors, usually referred as number of transistors, such as six-transistor (6T) SRAM, eight-transistor (8T) SRAM, etc. These transistors typically form a data latch to store a bit of data, while other transistors may be added to control the access of those transistors. SRAM cells are usually arranged in an array with multiple rows and columns. SRAM cells in each column are connected to a word line, which determines whether instant SRAM cells are selected or not. SRAM cells in each row are connected to a bit line (or a pair of complementary bit lines), which is used to write bit data to or read data from the SRAM cells.

With the rise of high-end computing applications in the semiconductor field nowadays, mere device miniaturization can no longer meet the high-density demands of SRAM. For example, SRAM cell structure in traditional planar transistors suffers from performance degradation and leakage issues when the semiconductor dimension is reduced below a certain extent. In order to overcome this problem, fin or multi-fin type 3D transistor architecture is proposed in the industry, namely fin field effect transistors (FinFETs). The application of FinFET in metal-oxide-semiconductor field-effect transistor (MOSFET) structures can effectively mitigate its short channel effect, and has properties like excellent subthreshold slope and high voltage gain.

Although the advances in FinFET technology have enabled the production of high-end FinFET SRAM devices, extremely small critical dimension required in advanced semiconductor technology is likely to cause problems in terms of semiconductor pattern features. For example, semiconductor patterns close to a boundary between cell regions and dummy regions may easily suffer from pattern anomaly issue due: to pattern affecting uneven density, normal interconnection between components, thereby causing yield loss of products. Therefore, in response to the demand for smaller electronic devices in high-end application market nowadays, how to solve this yield loss problem has become increasingly important and urgent.

### SUMMARY OF THE INVENTION

In order to cope with the aforementioned pattern anomaly issue prone to happen in FinFET device, the present invention hereby provides a semiconductor layout and method thereof, featuring dummy patterns in reflection symmetrical to normal patterns close to a boundary of semiconductor cell region, so as to prevent the pattern anomaly issue due to uneven pattern or feature density during process.

One aspect of the present invention is to provide a semiconductor layout with dummy patterns, including: a substrate with a cell region and a dummy region adjacent to each other; multiple fins spaced apart on the substrate and extending in a first direction; multiple gates on the substrate over the fins, the gates are spaced apart and extend in a second direction, and the second direction is perpendicular to the first direction; multiple slot contacts on the substrate between the gates and connected with the fins; multiple polysilicon contacts connected on the gates in the cell region; and multiple dummy polysilicon contacts on the gates in the dummy region closest to the cell region and not connected with any interconnects, wherein the dummy polysilicon contacts are in reflection symmetrical to the polysilicon contacts closest to a boundary between the dummy region and the cell region with respect to the boundary.

Another aspect of the present invention is to provide a method of manufacturing a semiconductor layout with dummy patterns, including: providing a substrate with a cell region and a dummy region adjacent to each other; forming multiple fins spaced apart and extending in a first direction on the substrate; forming multiple gates on the substrate, the gates are spaced apart and extend over the fins in a second direction, and the second direction is perpendicular to the first direction; forming multiple slot contacts on the substrate, the slot contact are connected on the fins between the gates; forming multiple polysilicon contacts on the gates, the polysilicon contacts are connected with the gates, wherein the polysilicon contacts in the dummy region are dummy polysilicon contacts, the dummy polysilicon contacts are on the gates closest to the cell region and not connected with any interconnects, and the dummy polysilicon contacts are in reflection symmetrical to the polysilicon contacts in the cell region closest to a boundary between the dummy region and the cell region with respect to the boundary.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a semiconductor layout with dummy patterns in accordance with the preferred embodiment of present invention;

FIG. 2 is a cross-section taken along a section line A-A′ in FIG. 1 in accordance with the preferred embodiment of present invention;

FIG. 3 is a SRAM layout with dummy patterns in accordance with one embodiment of present invention; and

FIG. 4 is a flow chart of manufacturing the semiconductor layout with dummy patterns in accordance with the preferred embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). In addition, spatially relative terms (e.g., “beneath,” “below,” “lower,” “above,” “upper” and the like) may be used herein for ease of description to describe one element or a relationship between a feature and another element or feature as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

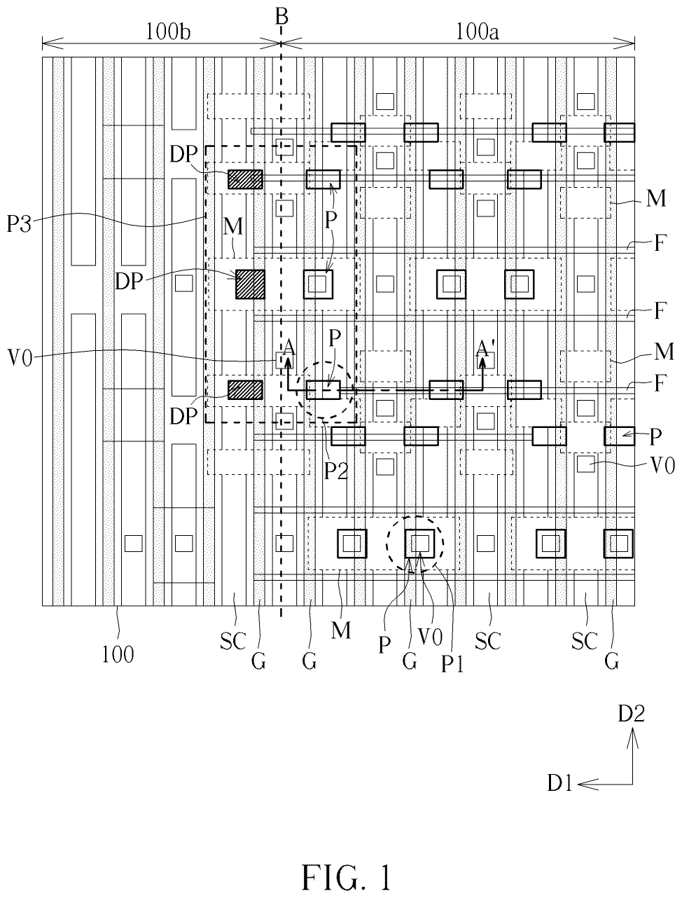

Firstly, please refer to FIG. 1, which is a semiconductor layout with dummy patterns in accordance with the preferred embodiment of present invention. The semiconductor layout of present invention includes a substrate 100 as a base for forming various devices, components or circuit in the layout. The substrate 100 is preferably made of silicon-based material, including but not limited to silicon, monocrystalline silicon, polysilicon, silicon-germanium (SiGe), carbon-doped silicon, amorphous silicon or the combination thereof. The material of substrate 100 may also be group III-V semiconductor, ex. gallium arsenide (GaAs) or silicon-on-insulator (SOI) substrate. In the preferred embodiment of present invention, a cell region 100a and a dummy region 100b are defined on the substrate 100. The two regions are adjacent to each other with a boundary B therebetween, wherein the cell region 100a is used for setting up semiconductor devices or circuit, ex. storage devices or transistors, capable of receiving and output signal or current. In comparison thereto, the dummy region 100b may function as an intermediate region or buffer region between the cell regions 100a in process or design rule, with semiconductor patterns set up thereon not involving actual circuit operation.

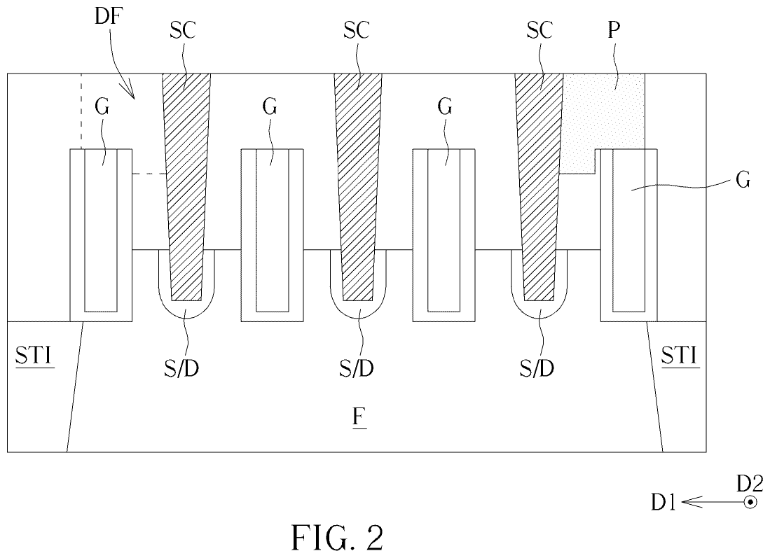

Refer still to FIG. 1, and FIG. 2 may be referred at the same time, which is a schematic cross-section taken along the section line A-A′ in FIG. 1 and may provide a more detail understanding about the relative relation and interconnection between layout patterns of the present invention in a vertical direction. Multiple fins F are set up on the substrate 100, spaced apart and extending in a first direction D1. The fins F may be formed protruding from the substrate 100 through photolithography process, with shallow trench isolations STI filled therebetween for isolating each other, thereby defining multiple active areas on the substrate 100. Furthermore, multiple gates G are set up on the substrate 100, spaced apart and extending in a second direction D2 over the fins F. The second direction D2 is preferably perpendicular to the first direction D1. The material of gate G may be polysilicon or metal, which may constitute transistor devices collectively with the fins F thereover, forming channel switches in the circuit. The fins F at two sides of the gate G may be considered as source/drain (S/D) of the transistors. In the embodiment of present invention, the gate G formed in the dummy region 100b is dummy gate, not involving in circuit operation.

Refer still to FIG. 1. Multiple slot contacts SC are further set up on the substrate 100, spaced apart between the gates G and extending in the first direction D1. Slot contact SC may be formed through steps of forming slot patterns first in a dielectric layer (ex. pre-metal dielectric layer, PMD) on the substrate 100 and then filling in metal material, including but not limited to TiN, Ta, TaN, Al, W or Cu. The Slot contacts SC are designedly connected with the fins F (i.e. source/drain S/D) at two sides of the gate G for connecting those parts to adjacent fins For circuits in upper layers. Please note in actual process, single contact slot SC may be divided into multiple segments, for example, the contact slot SC may be divided through adding a cutting mask M on the slot patterns in the step of forming the slot patterns, so that no slot pattern will be formed on the regions covered by the cutting mask M, meaning no slot contact SC will be formed in these covered regions thereafter. Single gate G may also be divided into multiple segments through photolithography process during manufacture, but not limited thereto. Similarly, the slot contact SC formed in the dummy region 100b is dummy slot contact SC, not involving in circuit operation. In certain embodiment, the slot contacts SC in the dummy region 100b will be removed.

Refer still to FIG. 1. In the embodiment of present invention, the slot contact SC may be connected to upper circuit through the vias V0 set up thereon, for example be connected to a first metal layer (M1) in BEOL (back-end-of-line) interconnects. The material of via V0 may be Cu or W. On the other hand, the gate G may also be connected to upper circuit through contacts. As shown in FIG. 2, polysilicon contact P may be set up and connected on the gate G, with its top plane preferably flush with top planes of the aforementioned slot contacts SC. The polysilicon contacts P may be formed after slot contacts SC by steps of performing a photolithography process to form recess patterns and then filling in polysilicon material in the recess patterns. With respect to polysilicon contacts P in the embodiment of present invention, the polysilicon contact P is formed and connected on the gate G without contacting any slot contact SC at a layout position having no slot contact SC formed therearound (as shown in the position P1 covered by the cutting mask M). The polysilicon contact P in this position would be further connected with a via V0 in order to connect an upper circuit through via V0. On the other hand, the polysilicon contact P at a layout position having slot contact SC formed therearound (as shown in the position P2 not covered by the cutting mask M) is formed and connected on the gate G, contacting the adjacent slot contact SC at the same time. As shown in FIG. 2, the polysilicon contact P and slot contact SC in this position may be connected to upper circuit through a common via V0. Alternatively, they may not be connected with any via V0.

In conventional skill, the polysilicon contact P near a boundary B between the cell region 100a and dummy region 100b (ex. the position P3 shown in FIG. 1) may easily suffer from pattern anomaly issue. This issue is caused by the atmosphere that there are no polysilicon contact P set up in normal dummy region, so that the critical dimension of polysilicon contact P close to the boundary B is likely to decrease due to abnormal exposure, thereby making the polysilicon contact P formed there shrink or even disappear, forming a defect DF as shown in FIG. 2. The presence of this defect DF may result in abnormal connection between the gate G and adjacent slot contact SC or the via V0 thereon, leading to the failure of corresponding transistor device and impacting product yield. This is a conventional issue to be solved in present invention.

To deal with the aforementioned issue, as shown in FIG. 1, dummy polysilicon contacts DP corresponding to the polysilicon contacts P are designedly set up on the dummy region 100b adjacent to the boundary B. The dummy polysilicon contacts DP are in reflection symmetrical to the polysilicon contacts P closest to the boundary B between the dummy region 100b and cell region 100a with respect to the boundary B. With this layout design, there will be no occurrence of abnormal pattern defects in the polysilicon contacts P near the boundary B, since the polysilicon contacts P at the position P2 are in an exposure atmosphere with corresponding patterns therearound in the stage of pattern definition, so that the exposure atmosphere of outmost polysilicon contacts P will be consistent with the one of polysilicon contacts P inside the cell region 100a, which is the advantage and innovative aspect of the present invention. The dummy polysilicon contact DP is set up and connected on the dummy gate G closest to the boundary B in the dummy region 100b, but the dummy polysilicon contact DP is not connected to upper circuit through any via V0 and doesn't involve in circuit operation, with all other aspects identical to polysilicon contact P.

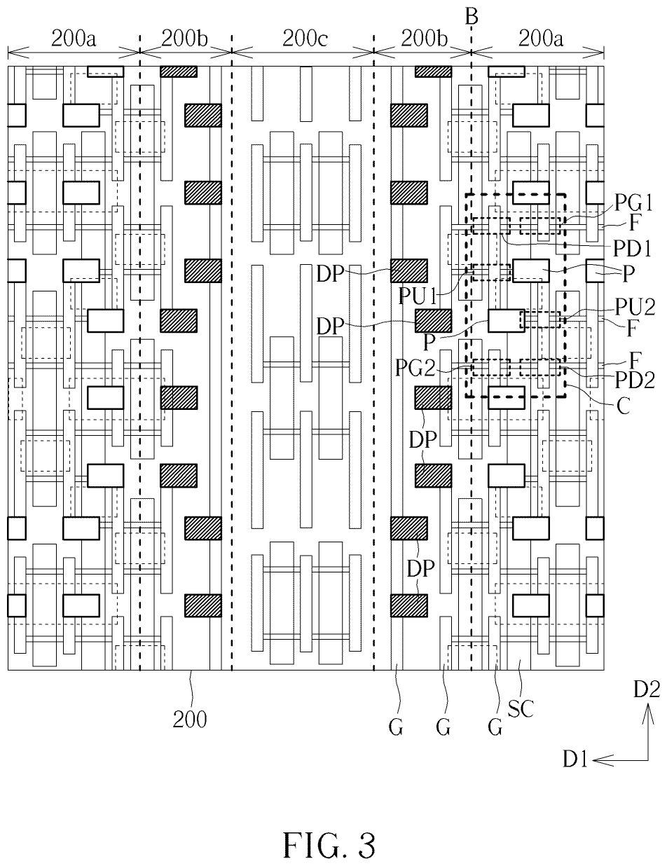

Please refer now to FIG. 3, which is a layout of SRAM with dummy patterns in the embodiment of present invention. The layout design of the aforementioned dummy polysilicon contact DP will be described in this embodiment under SRAM architecture. Different from the aforementioned embodiment, the gate G and polysilicon contact P in this embodiment are already divided into segments, forming specific transistors and circuit.

As shown in FIG. 3, the whole semiconductor layout is designed on a substrate 200. In this embodiment, regions like cell regions 200a, dummy regions 200b and a pickup region 200c (may also be referred as strip region) are defined on the substrate 200, wherein the dummy region 200b is positioned between the cell region 200a and pickup region 200c. The cell region 200a is used for setting up semiconductor devices and circuit, ex. storage devices or transistors capable of receiving and output signal or current. The dummy region 200b may function as an intermediate region or buffer region between the cell regions 200a in process or design rule, with semiconductor patterns formed thereon for evening pattern density on the layout plane and not involving actual circuit operation. The pickup region 200c may be a well pick-up (WPU) region, intermittent between the cell regions 200a every a predetermined interval of layout length, to provide a grounding path for the circuit or provide voltage/bias to N-well and P-well in the cell regions 200a

Refer still to FIG. 3. In the embodiment, the cell region 200a consists of multiple memory cells C. Under the architecture of 6T SRAM, each memory cell C is provided with six transistors and every transistor is constituted by intersecting gate G and fin F, including pull-up transistors PU1, PU2, pull-down transistors PD1, PD2 and pass-gate transistors PG1, PG2, wherein the pull-up transistors PU1, PU2 may be PMOS, the pull-down transistors PD1, PD2 and pass-gate transistors PG1, PG2 may be NMOS. The pull-up transistor PU1, PU2 and corresponding pull-down transistors PD1, PD2 constitute inverters, and the two inverters in the cell form a latch-up structure. In memory cell C, the pull-up transistor PU1, PU2 and pull-down transistors PD1, PD2 may implement high-level state (“1”) and low-level state (“0”) in storage nodes, while the pass-gate transistors PG1, PG2 may implement the access of bit lines.

Refer still to FIG. 3. In the embodiment, polysilicon contacts P are set up on parts of the gates G in the cell region 200a, for example at positions close to pass-gate transistors PG1, PG2. As described in prior art, the polysilicon contacts P close to the boundary B of cell region 200a may suffer from pattern anomaly issue due to uneven pattern density during manufacture. Regarding this issue, dummy polysilicon contacts DP corresponding to those polysilicon contacts P are designed on the dummy region 200b adjacent to the boundary B in the present invention. The dummy polysilicon contacts DP are set up and connected on the dummy gate G in the dummy region 200b, in reflection symmetrical to the polysilicon contacts P closest to the boundary B between the dummy region 200b and cell region 200a with respect to the boundary B. With this layout design, there will be no occurrence of abnormal pattern defects in the polysilicon contacts P near boundary B, since the polysilicon contacts P are in an exposure atmosphere with corresponding patterns therearound in the stage of pattern definition, so that its exposure atmosphere of polysilicon contacts P will be consistent with the one of polysilicon contacts P inside the cell region 200a, which is the advantage and innovative aspect of the present invention.

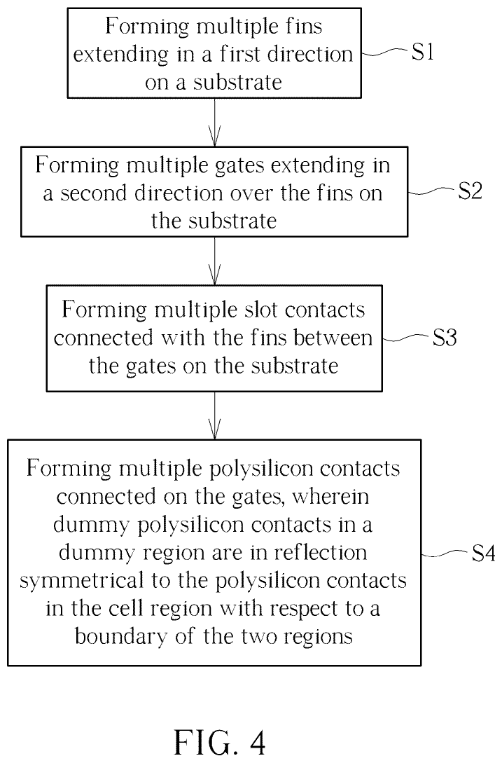

According to the aforementioned semiconductor structure, the present invention hereby provides a method of manufacturing a semiconductor layout with dummy patterns, with process steps shown as the flow chart in FIG. 4, and the layout of FIG. 1 may also be referred at the same time to provide a clearer understanding, including:

In step S1, provide a substrate 100 as a base for layout. The substrate 100 is defined with a cell region 100a and a dummy region 100b adjacent to each other, and multiple fins F are formed in the prepared substrate 100, for example through a photolithography process to etch the substrate 100. These fins F are spaced apart and extend in a first direction D1.

In step S2, form multiple gates G on the substrate 100. These gates G are spaced apart and extend in a second direction D2 over the fins F. The second direction D2 is preferably perpendicular to the first direction D1. This step may further include dividing the gates into multiple gate segments through photolithography process.

In step S3, form multiple slot contacts SC on the substrate 100. These slot contacts SC are positioned between those gates G and connected with the fins F, which may be formed by filling metal material into preformed slot patterns. This step may further include forming multiple segments of slot contacts SC by setting a cutting mask M on those slot patterns.

In step S4, form multiple polysilicon contacts P and DP on the gates G. These polysilicon contacts are connected with the gates G, wherein the polysilicon contacts in the dummy region 100b are dummy polysilicon contacts DP. The dummy polysilicon contacts DP are positioned on the gate G of the dummy region 100b and not connected with any interconnects, and the dummy polysilicon contacts DP are in reflection symmetrical to the polysilicon contacts P closest to a boundary B between the dummy region 100b and the cell region 100a with respect to the boundary B.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout with dummy patterns, comprising:
a substrate with a cell region and a dummy region adjacent to each other;
multiple fins spaced apart on said substrate and extending in a first direction;
multiple gates on said substrate over said fins, said gates are spaced apart extending in a second direction, and said second direction is perpendicular to said first direction;
multiple slot contacts on said substrate between said gates and connected with said fins;
multiple polysilicon contacts connected on said gates in said cell region; and
multiple dummy polysilicon contacts on said gates in said dummy region closest to said cell region and not connected with any interconnects, wherein said dummy polysilicon contacts are in reflection symmetrical to said polysilicon contacts closest to a boundary between said dummy region and said cell region with respect to said boundary.

2. The semiconductor layout with dummy patterns of claim 1, further comprising multiple vias connected on said slot contacts and said polysilicon contacts.

3. The semiconductor layout with dummy patterns of claim 1, wherein parts of said polysilicon contacts are connected with said slot contacts.

4. The semiconductor layout with dummy patterns of claim 1, further comprising multiple slot contact cutting mask on said slot contacts between said fins.

5. The semiconductor layout with dummy patterns of claim 1, wherein said slot contacts, said polysilicon contacts and said dummy polysilicon contacts are in a level between said substrate and semiconductor BEOL metal layers.

6. The semiconductor layout with dummy patterns of claim 1, wherein said gates in said dummy region are dummy gates, and said dummy polysilicon contacts are connected on said dummy gates.

7. The semiconductor layout with dummy patterns of claim 1, wherein said cell region comprises multiple SRAM cells, and further comprising a pull-up region at a side of said dummy region opposite to said cell region on said substrate.

8. A method of manufacturing a semiconductor layout with dummy patterns, comprising:
providing a substrate with a cell region and a dummy region adjacent to each other;
forming multiple fins spaced apart and extending in a first direction on said substrate;
forming multiple gates on said substrate, said gates are spaced apart and extend over said fins in a second direction, and said second direction is perpendicular to said first direction;
forming multiple slot contacts on said substrate, said slot contacts are connected on said fins between said gates;
forming multiple polysilicon contacts on said gates, said polysilicon contacts are connected with said gates, wherein said polysilicon contacts in said dummy region are dummy polysilicon contacts, said dummy polysilicon contacts are on said gates closest to said cell region and not connected with any interconnects, and said dummy polysilicon contacts are in reflection symmetrical to said polysilicon contacts in said cell region closest to a boundary between said dummy region and said cell region with respect to said boundary.

9. The method of manufacturing a semiconductor layout with dummy patterns of claim 8, further comprising forming multiple vias on said slot contacts and said polysilicon contacts in said cell region, said vias are connected with said slot contacts and said polysilicon contacts, and none of said vias are formed and connected on said dummy polysilicon contacts in said dummy region.

10. The method of manufacturing a semiconductor layout with dummy patterns of claim 8, further comprising forming multiple slot contact cutting mask on said slot contacts and between said fins.

11. The method of manufacturing a semiconductor layout with dummy patterns of claim 8, wherein said slot contacts and said polysilicon contacts are in a level between said substrate and semiconductor BEOL metal layers.

12. The method of manufacturing a semiconductor layout with dummy patterns of claim 8, wherein said gates in said dummy region are dummy gates, and said dummy polysilicon contacts are connected on said dummy gates.

13. The method of manufacturing a semiconductor layout with dummy patterns of claim 8, wherein said cell region comprises multiple SRAM cells, and further comprising a pull-up region at a side of said dummy region opposite to said cell region on said substrate.
